(19) United States
(12) Patent Application Publication
(10) Pub. No.: US 2009/0147648 A1
(43) Pub. Date: Jun. 11, 2009

(54) MAXIMUM LIKELIHOOD SEQUENCE ESTIMATION DECODING

(75) Inventor: Ruud Vlutters, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 12/295,763

(22) PCT Filed: Mar. 29, 2007
(86) PCT No.: PCT/IB07/51108

§ 371 Date: Oct. 2, 2008

(30) Foreign Application Priority Data
Apr. 4, 2006 (EP) 06112199.2

(51) Int. Cl. G11B 20/10; G11B 7/005; G11B 7/00; H03M 13/41

(52) U.S. Cl. 369/59.22; 375/341; G9B/20.009; G9B/7.018; G9B/7.019

(57) ABSTRACT

A Maximum Likelihood Sequence Estimator comprises a signal receiver (401) which receives a first signal for decoding. An ISI processor (403) generates a compensation signal from the first signal. The compensation signal represents intersymbol interference outside a channel model window of a Maximum Likelihood Sequence Estimation (MLSE) but does not represent intersymbol interference within the channel model window of the MLSE. A compensation processor (405) generates a compensated signal by compensating the first signal by the compensation signal, e.g. by subtracting the compensation signal from the first signal. The compensated signal is fed to a MLSE decoder (407) which decodes data of the first signal by performing the MLSE on the compensated signal. The invention may provide reduced detection error rates and may in particular be suitable for optical disc reading systems.

### FIELD OF THE INVENTION

The invention relates to Maximum Likelihood Sequence Estimation and in particular, but not exclusively, to Viterbi decoding for optical storage disc reading systems.

### BACKGROUND OF THE INVENTION

Methods and techniques for detecting and correcting bit errors in data processing or distribution systems are widely known. For example, communication systems wherein data is communicated over an unreliable communication link typically employ forward error correction coding and decoding to reduce the amount of communication errors. As another example, optical disc reading systems tend to employ error decoding in order to reduce the amount of reading errors.

A particularly efficient technique for detecting correct bit values in the presence of bit errors is known as Maximum Likelihood Sequence Estimation and specifically Partial Response Maximum Likelihood (PRML) bit detection. In particular, the Viterbi algorithm is commonly used for communication systems and data extraction from storage media, such as optical discs, in the presence of media and electronics noise.

Specifically, Viterbi based bit detection is frequently used in high-end modern optical disc systems in order to achieve reliable extraction of data stored on the optical disc. Furthermore, Viterbi bit detection is expected to play a major role for future generations of optical storage. In particular, the use of Viterbi detection allows an increment of the capacity of a Blu-ray™ Disc system from 25 GB to 35 GB per recording layer on a 12 cm disc.

In order to achieve efficient performance and a high reliability of the optical disc reader it is important that a high performance is achieved by the data decoding and in particular it is important that the accuracy of the Maximum Likelihood Sequence Estimator or Viterbi detector is optimised.

However, the Viterbi algorithm is relatively complex and requires large amounts of processing power and computational resource. Indeed, the associated hardware cost is one of the factors that currently limit an even wider acceptance of the algorithm in optical disc storage systems.

Accordingly, current approaches inherently require a trade-off between performance and complexity (e.g. computational complexity and/or hardware cost) and in practical systems the data detection performance accordingly tends to have a higher error rate than theoretically achievable.

Hence, an improved Maximum Likelihood Sequence Estimation, such as for an optical disc reader, would be advantageous and in particular a system allowing for increased flexibility, reduced complexity, reduced computational resource demand, increased applicability and/or improved performance would be advantageous.

### SUMMARY OF THE INVENTION

Accordingly, the Invention seeks to preferably mitigate, alleviate or eliminate one or more of the above mentioned disadvantages singly or in any combination.

According to a first aspect of the invention there is provided a Maximum Likelihood Sequence Estimator for decoding data of a first signal, the Maximum Likelihood Sequence Estimator comprising: receiving means for receiving the first signal; first means for generating a compensation signal from the first signal, the compensation signal representing intersymbol interference outside a channel model window of a Maximum Likelihood Sequence Estimation; second means for generating a compensated signal by compensating the first signal by the compensation signal; and means for decoding data of the first signal by performing the Maximum Likelihood Sequence Estimation on the compensated signal.

The invention may improve the performance of a Maximum Likelihood Sequence Estimator and may specifically improve data detection reliability. The invention may reduce the complexity of a Maximum Likelihood Sequence Estimator and/or may reduce the computational resource requirement. The invention may reduce hardware requirements and/or reduce cost for a Maximum Likelihood Sequence Estimator.

The inventor of the current invention have realised that improved performance can be achieved by pre-compensating a signal on which a Maximum Likelihood Sequence Estimation is based. In particular, the invention may reduce the degradation to Maximum Likelihood Sequence Estimator performance due to intersymbol interference. The invention may allow reduced intersymbol interference sensitivity for a given channel model length and may e.g. alleviate the requirement of the amount of intersymbol interference that must be taken into account by the Maximum Likelihood Sequence Estimation thereby reducing complexity. The invention may allow additional intersymbol interference reduction without degrading the operation of the Maximum Likelihood Sequence Estimation and may in particular allow a pre-compensation with reduced error propagation.

The Maximum Likelihood Sequence Estimator may be a Viterbi Maximum Likelihood Sequence Estimator.

According to an optional feature of the invention, the first means comprises: decoding means for decoding data from the first signal; third means for generating a second signal in response to the decoded data and a channel model of a first length, the first length being larger than the channel model window of the maximum likelihood sequence estimation; fourth means for generating the compensation signal in response to the second signal.

This may allow a practical, efficient implementation and/or high performance. In particular, the feature may allow efficient interference reduction without impacting the performance of the Maximum Likelihood Sequence Estimation.

The decoding means may be lower complexity and/or less reliable decoding means than the means for performing the Maximum Likelihood Sequence Estimation. The invention may provide reduced error propagation and in particular a reduced impact of detection errors by the decoding means on the decoding by the Maximum Likelihood Sequence Estimation may be achieved.

The second signal may represent an expected received signal for the decoded data and the channel model.

According to an optional feature of the invention, the third means comprises means for suppressing contributions associated with the channel model within the channel model window of the Maximum Likelihood Sequence Estimation.

This may allow a practical, efficient implementation and/or high performance. In particular, it may allow a low complexity and easy to implement way of reducing the degradation impact of the pre-compensation on the Maximum Likelihood Sequence Estimation.

According to an optional feature of the invention, the third means is arranged to set coefficients of the channel model within the channel model window of the Maximum Likelihood Sequence Estimation to substantially zero.

This may allow a practical, efficient implementation and/or high performance.

According to an optional feature of the invention, the first means further comprises: fourth means for generating a third signal in response to the decoded data and a channel model of a second length, the second length being substantially the same as the channel model window of the Maximum Likelihood Sequence Estimation; and wherein the fourth means comprises means for generating the compensation signal in response to a difference between the second signal and the third signal.

This may allow a practical, efficient implementation and/or high performance. In particular, it may allow a low complexity implementation which can effectively mitigate intersymbol interference outside the Maximum Likelihood Sequence Estimation channel model window with low impact on the intersymbol interference within the Maximum Likelihood Sequence Estimation channel model window.

According to an optional feature of the invention, the third means comprises a first Reference Level Unit and the fourth means comprises a second Reference Level Unit with fewer taps than the first Reference Level Unit.

This may allow a practical, efficient implementation and/or high performance. In particular, Reference Level Units may provide an efficient and automated adaptation to the received signal and the possible intersymbol conditions. Specifically, Reference Level Units may provide an automated adaptation of an implicit channel model.

According to an optional feature of the invention, the first Reference Level Unit comprises nine taps and the second Reference Level Unit comprises 5 taps.

This may allow a practical, efficient implementation and/or high performance. In particular, it may for optical disc readers provide a highly advantageous trade-off between complexity and performance.

According to an optional feature of the invention, the decoding means comprises means for determining data values by threshold decoding.

This may allow a practical, efficient implementation and/or high performance. In particular, it may allow the complexity of the pre-compensation to be kept low while allowing efficient performance. Specifically, the invention may allow a simple detection means to be used for mitigating intersymbol interference outside the Maximum Likelihood Sequence Estimation window without significant degradation impact (e.g. due to detection errors) on the intersymbol interference mitigation by the Maximum Likelihood Sequence Estimation.

According to another aspect of the invention, there is provided an optical disc reading apparatus comprising: a disc reader (101) for generating a first signal by reading an optical disc (103); and a Maximum Likelihood Sequence Estimator for decoding data of the first signal, the Maximum Likelihood Sequence Estimator comprising: receiving means for receiving a first signal, first means for generating a compensation signal from the first signal, the compensation signal representing intersymbol interference outside a channel model window of a Maximum Likelihood Sequence Estimation, second means for generating a compensated signal by compensating the first signal by the compensation signal, and means for decoding data of the first signal by performing the Maximum Likelihood Sequence Estimation on the compensated signal.

According to another aspect of the invention, there is provided a method of decoding data of a first signal, the method comprising receiving the first signal; generating a compensation signal from the first signal, the compensation signal representing intersymbol interference outside a channel model window of a Maximum Likelihood Sequence Estimation; generating a compensated signal by compensating the first signal by the compensation signal; and decoding data of the first signal by performing the Maximum Likelihood Sequence Estimation on the compensated signal.

These and other aspects, features and advantages of the invention will be apparent from and elucidated with reference to the embodiment(s) described hereinafter.

### BRIEF DESCRIPTION OF THE DRAWINGS

Embodiments of the invention will be described, by way of example only, with reference to the drawings, in which

FIG. 1 is illustrates an example of an optical disc reading apparatus in accordance with some embodiments of the invention;

FIG. 2 illustrates an example of a spectrum for a signal from an optical disc reader;

FIG. 3 illustrates an example of an error spectrum for a Viterbi estimator of an optical disc reader;

FIG. 4 illustrates an apparatus for performing a Maximum Likelihood Sequence Estimation in accordance with some embodiments of the invention;

FIG. 5 illustrates an example of a channel response in an optical disc reader;

FIG. 6 illustrates an apparatus for performing pre-compensation for a Maximum Likelihood Sequence Estimation in accordance with some embodiments of the invention; and

FIG. 7 illustrates an example of a Reference Level Unit.

### DETAILED DESCRIPTION OF SOME EMBODIMENTS OF THE INVENTION

The following description focuses on embodiments of the invention applicable to an optical disc reading system using a Maximum Likelihood Sequence Estimator for data detection. However, it will be appreciated that the invention is not limited to this application but may be applied to many other decoding systems including for example decoders for communication systems.

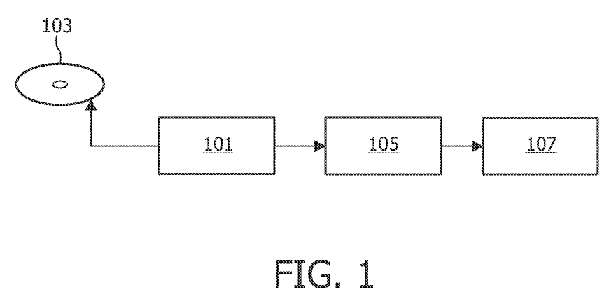

FIG. 1 illustrates an example of an optical disc reading apparatus in accordance with some embodiments of the invention.

In the example, an optical disc data reader 101 reads data from an optical disc 103. The data stored on the optical disc 101 is RLL (Run Length Limited) coded. The data samples read from the optical disc are fed from the optical disc data reader 101 to a Maximum Likelihood Sequence Estimator which specifically is a Viterbi bit detector 105. The Viterbi bit detector 105 uses at the Viterbi algorithm to determine the data values which are read from the optical disc 103. The detected data is fed to a data interface 107 which interfaces to external equipment. For example the data interface 107 may provide an interface to a personal computer.

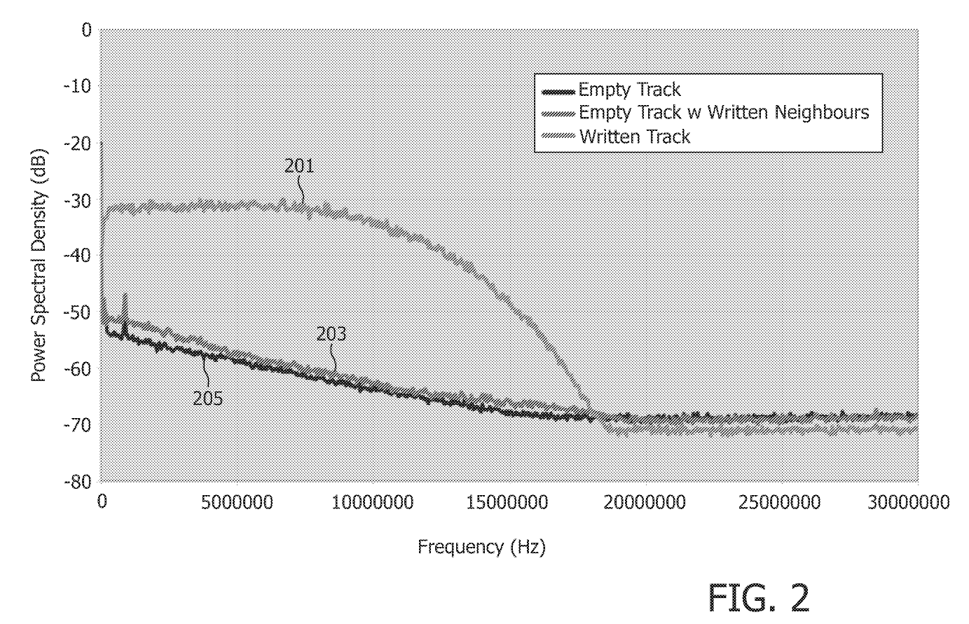

In optical disc reading apparatuses, it has been observed that the performance of Viterbi estimators tend to be less than expected. In particular, it has been observed that the spectral characteristics of the errors of the Viterbi estimator deviate from the spectral characteristics of the signal being fed to the Viterbi estimator. For example, FIG. 2 illustrates a measured output from a spectrum analyser applied to the input of a Viterbi estimator. In the example, curve 201 illustrates the spectrum of a written track, curve 203 illustrates the spectrum of an empty track with written neighbours and curve 205 illustrates the spectrum of an empty track with empty neighbours.

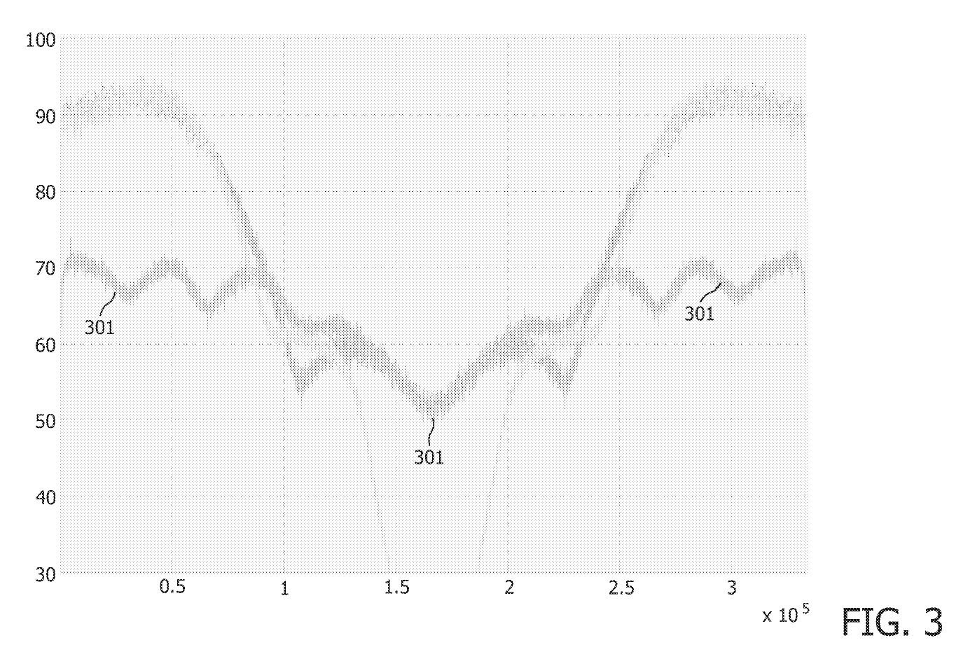

As illustrated, if the tracks are empty, the spectrum will be dominated by media noise which is relatively white (i.e. constant) although some decrease with increasing frequency is noted. It should be expected that the error spectrum would have a similar characteristic but instead characteristics such as indicated by curve 301 of FIG. 3 are typically obtained for the error spectrum of a Viterbi estimator.

The Inventor of the current invention has realised that this behaviour is at least partly due to InterSymbol Interference (ISI) which results in colored noise and in a reduced performance of the Viterbi estimator.

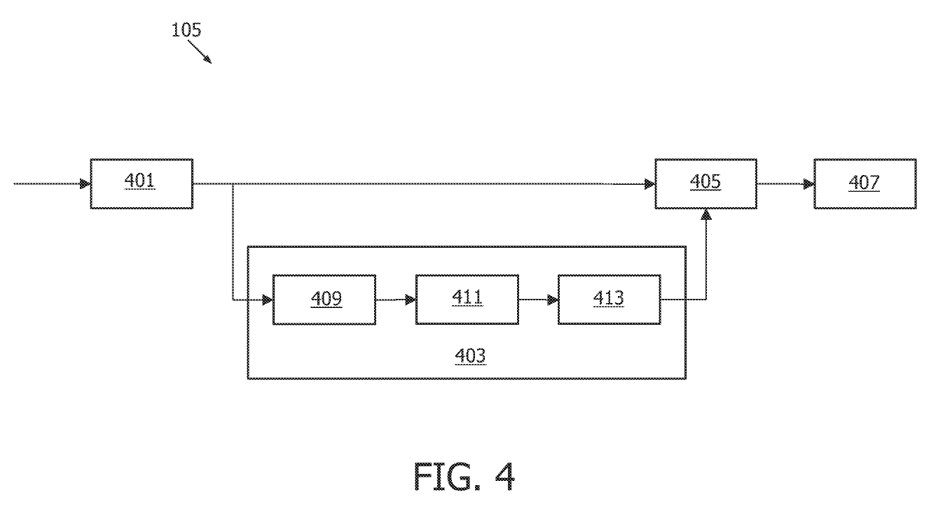

FIG. 4 illustrates an example of a Maximum Likelihood Sequence Estimator in accordance with some embodiments of the invention. The Maximum Likelihood Sequence Estimator can specifically be the Viterbi bit detector 105 of FIG. 1 and will be described with reference thereto.

The Viterbi bit detector 105 comprises a signal receiver 401 which receives the signal from the from the optical disc data reader 101. The signal receiver 401 is coupled to an ISI processor 403 and a compensation processor 405.

The ISI processor 403 is arranged to generate a compensation signal from the first signal. The compensation signal is a signal which reflects the intersymbol interference resulting from data symbols which are outside the channel model window that is used by the Maximum Likelihood Sequence Estimation (MLSE) of the Viterbi bit detector 105.

Specifically, for a given signal sample of the signal from the signal receiver 401, the ISI processor 403 estimates a signal component which arises from optical data spots that are outside the window which is considered by the MLSE. Thus, this signal component represents a distortion of the signal which results from the media and which is not taking into account by the MLSE. It this represents a contribution which will behave as additional noise at the input of the MLSE. At the same time, the signal component ideally does not comprise any contribution from any optical data points that are within the window considered by the MLSE.

The ISI processor 403 is coupled to the compensation processor 405. The compensation processor 405 is arranged to generate a compensated signal by compensating the signal from the signal receiver 401 by the compensation signal from the ISI processor 403. In the specific example, the compensation processor 405 simply subtracts the compensation signal from the signal from the signal receiver 401. Accordingly, in the ideal case, the compensation processor 405 removes any contributions to the signal samples from optical data points which are not considered by the MLSE for that signal sample.

The compensation processor 405 is coupled to a MLSE in the form of a Viterbi decoder 407. The operation of MLSEs and Viterbi decoders e.g. for optical disc reading systems will be well known to the person skilled in the art and will for brevity and clarity not be described further herein.

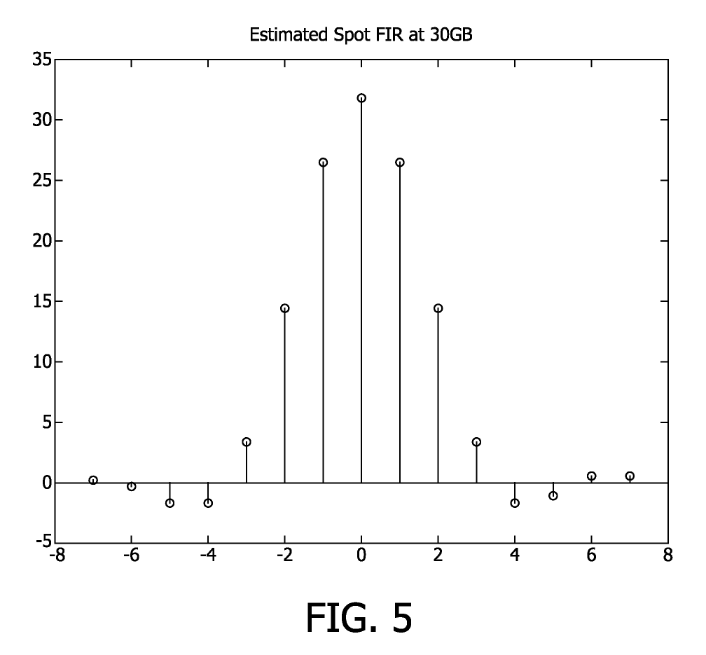

FIG. 5 illustrates an example of a typical contribution to a signal sample from surrounding symbol samples for a given optical data point (in other words FIG. 5 can be considered to illustrate the channel which a given data value is convolved with). As illustrated, the symbol shape/channel resembles a sin x/x function with a number of lobes of reducing amplitude (often referred to as Airy lopes).

In order to ensure reliable data detection, the MLSE comprises a channel model which reflects the channel for a given data point. This channel model is used to determine the expected signal samples for given input data and is thus used to determine metric values for the different state transitions. However, in order to maintain low complexity the channel model is typically of limited size. For example, typical Viterbi detectors in optical disc readers often use a channel model with a window of five symbol samples. However, this limits the considered intersymbol interference to two symbols on each side of the current symbol. As the contribution from other symbols may be quite significant, a degradation of the MLSE performance results. For example, in the example of FIG. 5, the contribution from the data symbols 3, 4 and 5 symbols removed from the current symbol (in either direction) is quite significant.

In the example of FIG. 4, the ISI processor 403 generates a compensated signal which for each signal sample corresponds to the intersymbol interference contribution from data symbols which are outside the window of the MLSE. Thus, in the specific example, the compensated signal represents the contribution from symbols which are e.g. 3, 4 and 5 symbols removed from the current symbol (in either direction).

The compensation processor 405 subtracts this additional intersymbol interference contribution from the received signal but does not affect the contribution of the ISI within the window of the MLSE. Thus, the ISI is reduced without affecting the operation of the MLSE and especially without creating distortion that will degrade the MLSE performance. Thus, in the described embodiments, instead of suppressing ISI from direct neighbouring symbols (as in conventional ISI cancellation), only those contributions from symbols that are outside the span of the Viterbi detector are suppressed. This improves Viterbi detection performance significantly, while having almost no error propagation caused by erroneous data decisions used for generating the compensation signal.

It will be appreciated that any suitable method or algorithm for generating the compensation signal may be used.

In the example of FIG. 4, the ISI processor 403 comprises a decoder 409 which decodes the data from the received signal. In the example, the decoder 409 uses a much simpler decoding algorithm then the Viterbi decoder 407. Thus, the decoder 409 uses a very simple algorithm or decoding criterion which provides estimated data with very low complexity and potentially with a much higher error rate than what is required from the Viterbi decoder 407. In the specific example, a simple threshold detection is used. Specifically, if the current simple sample is above a predetermined threshold the data is determined as a first binary value, and if it is below the predetermined threshold the data value is determined as the opposite binary value.

The decoder 409 is coupled to a signal estimator 411. The signal estimator 411 comprises a channel model that is longer than the channel model used by the MLSE. For example, a channel model corresponding to the values given by FIG. 5 may be used but in contrast to the Viterbi decoder 407, the signal estimator 411 may include e.g. 7, 9 or 11 symbol values.

The signal estimator is arranged to determine a signal that corresponds to the signal which is expected from the signal receiver 401 given the decoded data and the channel model. For example, the channel model can be represented as a FIR filter which is convolved with the estimated data value to produce the estimated signal. This estimated signal thus represents the signal that would be received by the signal receiver 401 if the correct data was identical to the estimated data, if the channel was identical to the channel model and if there were no other contributions.

The signal estimator 411 is coupled to an output processor 413 which generates the compensated signal from the estimated signal and which feeds it to the compensation processor 405.

The signal which is output from the output processor 413 comprises the contributions from the symbols outside the window of the MLSE whereas the contributions within the window have been suppressed.

It will be appreciated that this suppression can be performed as a post processing or can be an inherent part of the processing whereby e.g. the estimated signal is generated to only comprise contributions from outside the MLSE window.

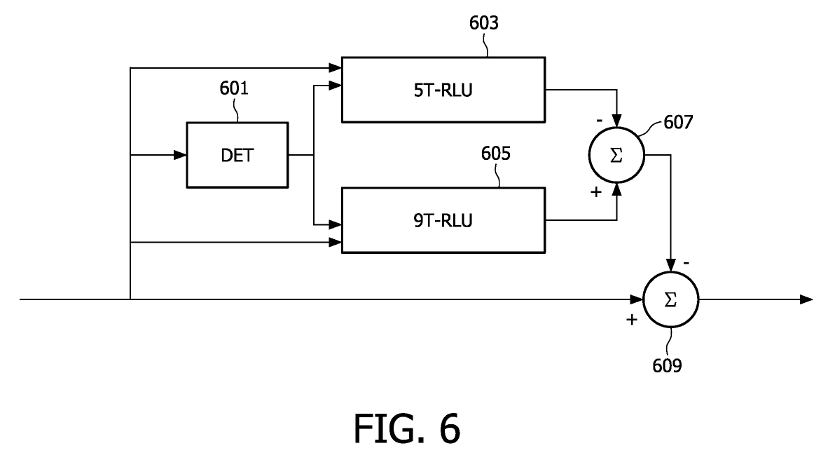

An example of a pre-compensation in accordance with some embodiments of the invention is illustrated in FIG. 6. The example may specifically be implemented by the apparatus of FIG. 4.

In this example, a detector 601 (corresponding to detector 409) generates preliminary data bits based on the received signal. A simple threshold detection resulting in a relatively high error rate can be used in many embodiments. The detected data is fed to two parallel Reference Level Units (RLU) 603, 605. RLUs are known to the person skilled in the art but for clarity a brief explanation is provided in the following.

An RLU provides an automatic and implicit adaptation of a channel model to the measured system by determining an average value for all possible data combinations of a given length. Reference levels can be seen as the average value of the signal for a given modulation bit sequence.

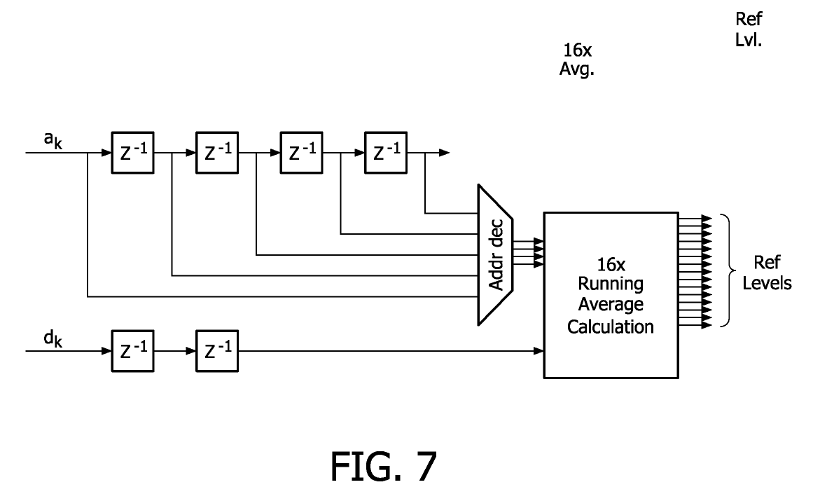

An example of a possible implementation of a five-tap (considering five symbol value combinations) RLU is shown in FIG. 7. The (preliminary) detected modulation bits aₖ are entering together with the synchronised received signal dₖ. For each clock-cycle, 5 modulation bits are transformed into a 4 bit address, pointing to one of the 16 reference levels. Next this reference value is then updated by the value of the received dₖ. e.g. according to:

RLᵢ(k)=(1−α)×RLᵢ(k−1)+α×d(k)

where α is a suitable filter coefficient which is typically very small (e.g. around 0.01).

It will be appreciated that in this example, only 16 reference levels are considered for combinations of 5 data bits. However, due to the Run Length Limitation typically used on optical reading systems, the number of valid data combinations will be lower than the number of possible data combinations.

Thus, the RLU generates maintains a low pass filtered or average signal value for different data bit combinations. For example, for an input sequence of 11111, the RLU maintains a reference value which corresponds to the average signal value that has previously been measured for this bit combination. Thus, the RLU inherently implements a channel model which indicates the expected signal value output from the channel for a given bit combination. This value is automatically generated and maintained as the low pass filtered value previously obtained and the RLU this implicitly generates an automated and adaptive generation of a channel model.

In the example of FIG. 6, the first RLU 603 (which may be implemented by the output processor 413) has a number of taps corresponding to the channel model window of the MLSE—in the specific example a five-tap RLU is used. Thus, the reference levels of the first RLU indicate the expected (average value) of the signal for the decoded data and the channel model window of the MLSE. In other words, the reference levels are determined for a channel which has a length of five data symbols corresponding to the five data symbols used by the MLSE.

The second RLU 605 (which may be implemented by the signal estimator 411) has a larger number of taps and thus generates an expected signal for a channel model that takes into account symbols outside the MLSE channel model window. In the specific case, a nine-tap RLU is used.

Thus, the outputs of the RLUs 603, 605 are the running average signal values from the signal receiver 401 for the input bits determined by the detector 601. However, whereas one output only takes into account the symbols considered by the MLSE, the other output takes more symbols into account and thus represents a further intersymbol interference contribution. This specifically may comprise contributions for the Airy lopes of an optical spot.

The output of the first RLU 603 is subtracted from the output of the second RLU 605 by a first subtractor 607 (e.g. implemented by the output processor 413). This results in a compensation signal which only reflects intersymbol interference outside the window of the MLSE and with the contributions from within the window suppressed. Thus, this signal can especially reflect the intersymbol interference contribution from the Airy lobes.

The first subtractor 607 is coupled to a second subtractor 609 (which may be implemented by the compensation processor 405) which subtracts the compensated signal from the original signal from the signal receiver 401. Thus, the output of the second subtractor 609 corresponds to the original signal but compensated for intersymbol interference which is outside of the window considered by the MLSE. This, results in a less noisy input signal to the Viterbi detector 109 and thus in a reduced error rate and improved performance.

In particular, the described approach may not only remove the intersymbol interference from the Airy lobes from the input to the MLSE, but may also reduce non-linearities that can be captured by the 9 tap reference levels but not by the 5 tap reference levels (such as run-length dependent edge shifts for short I2/I3/I4 run lengths).

Simulations have specifically shown that an error spectrum much closer resembling the media noise can be achieved. Furthermore, an MLSE window of five symbols combined with a pre-compensation window of 9 symbols (corresponding to the use of 5 and 9 tap RLUs) have been found to provide highly advantageous performance for optical disc reading systems.

In the example of FIG. 6, the RLUs were used to generate expected data values by a determination of reference levels. Thus, in the example no explicit channel model is generated (rather this is implicitly represented by the reference levels that depend on the experienced channel).

It will be appreciated that in other embodiments, the ISI processor 403 may explicitly generate a channel estimate representing the intersymbol interference. For example, an explicit channel model may be determined in accordance with any known technique (such as a Least Mean Square method) and the resulting channel model can be used to determine the estimated signal.

For example, the signal estimator 411 may directly determine the estimated signal as the compensation signal with the signal components within the MLSE window being suppressed.

This can for example be achieved by modifying the channel model by setting all coefficients within the window of the MLSE to zero. E.g. for the example of FIG. 5, the coefficients for the current symbol and the two surrounding symbols on each side can be set to zero. The detected data bits from the detector 409 can then be convolved with the modified channel model to directly generate the compensation signal that can be fed to the compensation processor 405.

It will be appreciated that the above description for clarity has described embodiments of the invention with reference to different functional units and processors. However, it will be apparent that any suitable distribution of functionality between different functional units or processors may be used without detracting from the invention. For example, functionality illustrated to be performed by separate processors or controllers may be performed by the same processor or controllers. Hence, references to specific functional units are only to be seen as references to suitable means for providing the described functionality rather than indicative of a strict logical or physical structure or organization.

The invention can be implemented in any suitable form including hardware, software, firmware or any combination of these. The invention may optionally be implemented at least partly as computer software running on one or more data processors and/or digital signal processors. The elements and components of an embodiment of the invention may be physically, functionally and logically implemented in any suitable way. Indeed the functionality may be implemented in a single unit, in a plurality of units or as part of other functional units. As such, the invention may be implemented in a single unit or may be physically and functionally distributed between different units and processors.

Although the present invention has been described in connection with some embodiments, it is not intended to be limited to the specific form set forth herein. Rather, the scope of the present invention is limited only by the accompanying claims. Additionally, although a feature may appear to be described in connection with particular embodiments, one skilled in the art would recognize that various features of the described embodiments may be combined in accordance with the invention. In the claims, the term comprising does not exclude the presence of other elements or steps.

Furthermore, although individually listed, a plurality of means, elements or method steps may be implemented by e.g. a single unit or processor. Additionally, although individual features may be included in different claims, these may possibly be advantageously combined, and the inclusion in different claims does not imply that a combination of features is not feasible and/or advantageous. Also the inclusion of a feature in one category of claims does not imply a limitation to this category but rather indicates that the feature is equally applicable to other claim categories as appropriate. Furthermore, the order of features in the claims do not imply any specific order in which the features must be worked and in particular the order of individual steps in a method claim does not imply that the steps must be performed in this order. Rather, the steps may be performed in any suitable order. In addition, singular references do not exclude a plurality. Thus references to “a”, “an”, “first”, “second” etc do not preclude a plurality. Reference signs in the claims are provided merely as a clarifying example shall not be construed as limiting the scope of the claims in any way.

1. A Maximum Likelihood Sequence Estimator for decoding data of a first signal, the Maximum Likelihood Sequence Estimator comprising:
receiving means (401) for receiving the first signal;
first means (403) for generating a compensation signal from the first signal, the compensation signal representing intersymbol interference outside a channel model window of a Maximum Likelihood Sequence Estimation;
second means (405) for generating a compensated signal by compensating the first signal by the compensation signal; and
means (407) for decoding data of the first signal by performing the Maximum Likelihood Sequence Estimation on the compensated signal.

2. The Maximum Likelihood Sequence Estimator of claim 1 wherein the first means comprises:
decoding means (409) for decoding data from the first signal;
third means (411) for generating a second signal in response to the decoded data and a channel model of a first length, the first length being larger than the channel model window of the maximum likelihood sequence estimation; and
fourth means (413) for generating the compensation signal in response to the second signal.

3. The Maximum Likelihood Sequence Estimator of claim 2 wherein the third means (411) comprises means for suppressing contributions associated with the channel model within the channel model window of the Maximum Likelihood Sequence Estimation.

4. The Maximum Likelihood Sequence Estimator of claim 3 wherein the third means (411) is arranged to set coefficients of the channel model within the channel model window of the Maximum Likelihood Sequence Estimation to substantially zero.

5. The Maximum Likelihood Sequence Estimator of claim 2 wherein the first means (403) further comprises:
fourth means for generating a third signal in response to the decoded data and a channel model of a second length, the second length being substantially the same as the channel model window of the Maximum Likelihood Sequence Estimation;
and wherein the fourth means comprises means for generating the compensation signal in response to a difference between the second signal and the third signal.

6. The Maximum Likelihood Sequence Estimator of claim 5 wherein the third means (411) comprises a first Reference Level Unit (605) and the fourth means comprises a second Reference Level Unit (603) with fewer taps than the first Reference Level Unit (605).

7. The Maximum Likelihood Sequence Estimator of claim 6 wherein the first Reference Level Unit (605) comprises nine taps and the second Reference Level Unit (603) comprises 5 taps.

8. The Maximum Likelihood Sequence Estimator of claim 2 wherein the decoding means (409) comprises means for determining data values by threshold decoding.

9. An optical disc reading apparatus comprising:
a disc reader (101) for generating a first signal by reading an optical disc (103); and
a Maximum Likelihood Sequence Estimator (105) for decoding data of the first signal, the Maximum Likelihood Sequence Estimator (105) comprising:
receiving means (401) for receiving a first signal,
first means (403) for generating a compensation signal from the first signal, the compensation signal representing intersymbol interference outside a channel model window of a Maximum Likelihood Sequence Estimation,
second means (405) for generating a compensated signal by compensating the first signal by the compensation signal, and
means for (407) decoding data of the first signal by performing the Maximum Likelihood Sequence Estimation on the compensated signal.

10. A method of decoding data of a first signal, the method comprising
receiving the first signal;
generating a compensation signal from the first signal, the compensation signal representing intersymbol interference outside a channel model window of a Maximum Likelihood Sequence Estimation;
generating a compensated signal by compensating the first signal by the compensation signal; and
decoding data of the first signal by performing the Maximum Likelihood Sequence Estimation on the compensated signal.
